(19) United States
(12) Patent Application Publication
(10) Pub. No.: US 2023/0391969 A1
(43) Pub. Date: Dec. 7, 2023

(54) LAMINATE

(71) Applicant: NITTO DENKO CORPORATION, Ibaraki-shi, Osaka (JP)

(72) Inventors: Nozomi Fujino, Osaka (JP); Taisuke Karasuda, Osaka (JP)

(73) Assignee: NITTO DENKO CORPORATION, Ibaraki-shi, Osaka (JP)

(21) Appl. No.: 18/035,325

(22) PCT Filed: Aug. 4, 2022
(86) PCT No.: PCT/JP2022/029989

§ 371 Date: May 4, 2023

(30) Foreign Application Priority Data
Aug. 6, 2021 (JP) 2021-130170

(51) Int. Cl. C08J 7/04; C09D 133/08; C23C 14/08

(52) U.S. Cl. CPC C08J 7/0423; C09D 133/08; C23C 14/086; C08J 2333/08; C08J 2367/02

(57) ABSTRACT

A laminate (1) includes an underlayer (3) and a crystalline transparent electrically conductive layer (4) adjacent to a one surface (31) in a thickness direction of the underlayer (3). The underlayer (3) includes a resin. A one surface (41) in the thickness direction of the transparent electrically conductive layer (4) includes a first ridge (42) having a height of 3 nm or more. The one surface (31) of the underlayer (3) may include a second ridge (32) having a height of 3 nm or more, and the second ridge (32) is not overlapped with the first ridge (42) when projected in the thickness direction.

### TECHNICAL FIELD

The present invention relates to a laminate.

### BACKGROUND ART

A laminate which includes an underlayer, and a crystalline transparent electrically conductive layer adjacent to the underlayer is known (ref: for example, Patent Document 1 below). In the laminate described in Patent Document 1, a one surface in a thickness direction of the transparent electrically conductive layer has a first ridge. A one surface in the thickness direction of the underlayer has a second ridge. The second ridge of the underlayer is overlapped with the first ridge of the transparent electrically conductive layer when projected in the thickness direction.

In production of the laminate of Patent Document 1, the second ridge corresponding to shapes of particles is formed in the underlayer by coating a resin composition containing the particles. In addition, a thin film is formed on the one surface in the thickness direction of the underlayer, and the first ridge following the above-described second ridge is formed on the transparent electrically conductive layer.

### CITATION LIST

### Patent Document

Patent Document 1: Japanese Unexamined Patent Publication No. 2017-122992

### SUMMARY OF THE INVENTION

### Problem to be Solved by The Invention

The transparent electrically conductive layer is made crystalline by heating an amorphous transparent electrically conductive layer. However, in the laminate of Patent Document 1, orientation of crystals is hardly aligned in crystallization of the amorphous transparent electrically conductive layer due to the above-described second ridge, that is, growth of the crystals is inhibited, and therefore, there is a problem that specific resistance of the crystallized transparent electrically conductive layer is increased.

On the other hand, when another layer is disposed on the one surface in the thickness direction of the transparent electrically conductive layer, adhesion between the transparent electrically conductive layer and the above-described layer is also required. Examples of the other layer include coating layers.

The present invention provides a laminate including a transparent electrically conductive layer having low specific resistance and excellent adhesion to another layer.

### Means for Solving the Problem

The present invention (1) includes a laminate including an underlayer and a crystalline transparent electrically conductive layer adjacent to a one surface in a thickness direction of the underlayer, wherein the underlayer includes a resin, a one surface in the thickness direction of the transparent electrically conductive layer includes a first ridge having a height of 3 nm or more, the one surface of the underlayer may include a second ridge having a height of 3 nm or more, and the second ridge is not overlapped with the first ridge when projected in the thickness direction.

The present invention (2) includes the laminate described in (1), wherein the number of the first ridge per unit length is greater than the number of the second ridge per unit length.

The present invention (3) includes the laminate described in (1) or (2), wherein the underlayer does not include the second ridge.

The present invention (4) includes the laminate described in any one of (1) to (3), wherein the transparent electrically conductive layer includes a grain boundary having an end edge leading to the one surface of the transparent electrically conductive layer, and a ridge starting portion at which the first ridge starts ridging is located at or near the end edge.

### Effect of the Invention

A transparent electrically conductive layer of the laminate of the present invention has low specific resistance and has excellent adhesion to another layer.

### BRIEF DESCRIPTION OF THE DRAWINGS

FIG. 1 shows a cross-sectional view of one embodiment of a laminate of the present invention.

FIG. 2 shows a modified example of a laminate.

FIG. 3 shows a modified example of a laminate.

FIG. 4 shows an image processed view of a TEM image of Example 1.

FIG. 5 shows an image processed view with an auxiliary line added to FIG. 4.

FIG. 6 shows a graph illustrating a relationship between an oxygen introduction amount and specific resistance in reactive sputtering in a first step.

FIG. 7 shows a schematic cross-sectional view of Comparative Example 2.

### DESCRIPTION OF EMBODIMENTS

### 1. One Embodiment of Laminate

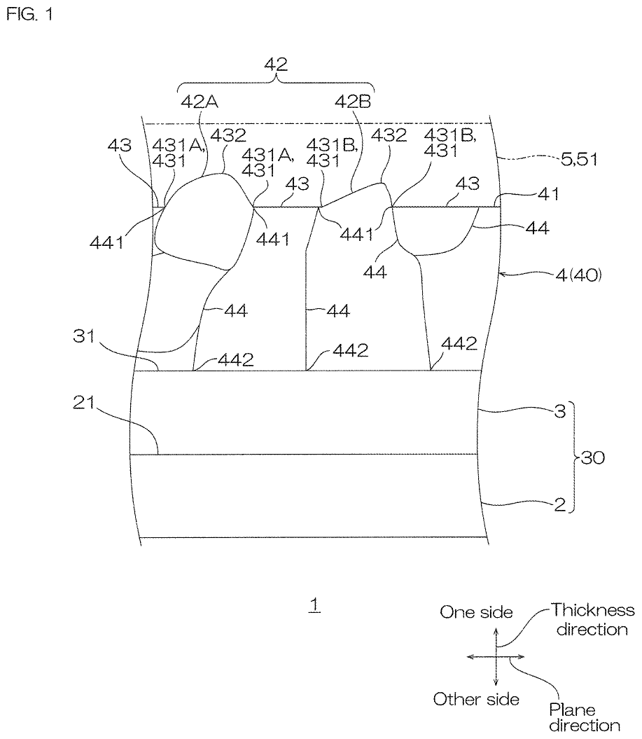

One embodiment of a laminate of the present invention is described with reference to FIG. 1.

A laminate 1 extends in a plane direction. The plane direction is perpendicular to a thickness direction. The laminate 1 has, for example, a generally rectangular shape when viewed from the top. The view from the top refers to viewing in the thickness direction. Specifically, the laminate 1 has a sheet shape. The sheet includes a film. The sheet and the film are not clearly distinguished.

In the present embodiment, the laminate 1 includes a substrate layer 2, an underlayer 3, and a transparent electrically conductive layer 4 in order toward one side in the thickness direction. Specifically, the laminate 1 includes the substrate layer 2, the underlayer 3 disposed on a one surface 21 in the thickness direction of the substrate layer 2, and the transparent electrically conductive layer 4 disposed on a one surface 31 in the thickness direction of the underlayer 3. The two layers adjacent in the thickness direction are adjacent to each other.

1.1 Substrate Layer 2

The substrate layer 2 is disposed on the opposite side of the transparent electrically conductive layer 4 with respect to the underlayer 3 in the thickness direction. The substrate layer 2 has a sheet shape. The substrate layer 2 is preferably transparent.

Examples of a material for the substrate layer 2 include resins. In other words, the substrate layer 2 includes the resin. Examples of the resin include polyester resins, acrylic resins, olefin resins, polycarbonate resins, polyether sulfone resins, polyarylate resins, melamine resins, polyamide resins, polyimide resins, cellulose resins, polystyrene resins, and norbornene resins. As the resin, preferably, a polyester resin is used from the viewpoint of transparency and mechanical strength. Examples of the polyester resin include polyethylene terephthalate (PET), polybutylene terephthalate, and polyethylene naphthalate, and preferably, PET is used. A thickness of the substrate layer 2 is, for example, 5 μm or more, preferably 10 μm or more, and for example, 500 μm or less, preferably 200 μm or less, more preferably 100 μm or less.

The one surface 21 in the thickness direction of the substrate layer 2 may have a third ridge having a height of 3 nm or more. The height of the third ridge is determined in the same manner as the height of a first ridge 42 to be described later. The position and the number of the above-described third ridge when viewed from the top are not limited.

Total light transmittance of the substrate layer 2 is, for example, 70% or more, preferably 80% or more, more preferably 85% or more. The upper limit of the total light transmittance of the substrate layer 2 is not limited. The total light transmittance of the substrate layer 2 is determined based on JIS K 7375-2008.

1.2 Underlayer 3

The underlayer 3 is adjacent to one side in the thickness direction of the substrate layer 2. Specifically, the underlayer 3 is in contact with the one surface 21 in the thickness direction of the substrate layer 2. The underlayer 3 is preferably transparent. Examples of the underlayer 3 include optical adjustment layers and hard coat layers. The underlayer 3 is a single layer or a plurality of layers.

The substrate layer 2 and the underlayer 3 may be referred to as a substrate 30. That is, the substrate 30 includes the substrate layer 2 and the underlayer 3 in order toward one side in the thickness direction. The substrate 30 is preferably transparent. Therefore, the substrate 30 may be referred to as a transparent substrate 30.

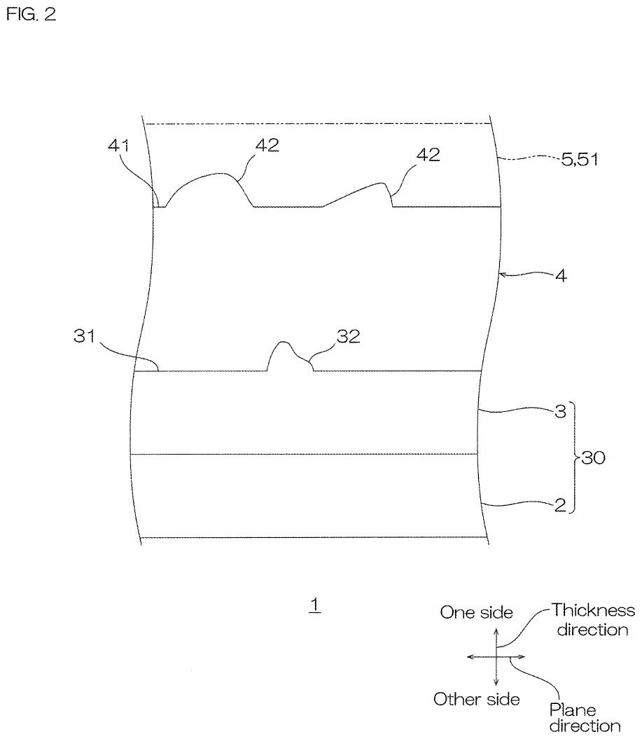

The underlayer 3 includes a resin, and may further include, for example, particles. Preferably, the underlayer 3 does not contain the particles, while containing the resin. In the present embodiment, when the underlayer 3 does not contain the above-described particles, the one surface 31 in the thickness direction of the underlayer 3 does not include a second ridge 32 (ref: FIG. 2), and the one surface 31 can be formed as a preferable flat surface. Examples of the resin include acrylic resins, urethane resins, melamine resins, alkyd resins, and silicone resins. When a raw material for the resin is a curable resin, the underlayer 3 is formed as a cured film.

In the present embodiment, the one surface 31 in the thickness direction of the underlayer 3 does not include the second ridge 32 whose height is 3 nm or more. In other words, the one surface 31 in the thickness direction of the underlayer 3 is a flat surface. In the flat surface, a presence of a ridge having a height of below 3 nm is allowed.

In the present embodiment, since the one surface 31 in the thickness direction of the underlayer 3 does not include the above-described second ridge 32 (ref: FIG. 2), orientation of crystals in the transparent electrically conductive layer 4 to be described next is well aligned, and therefore, the specific resistance of the transparent electrically conductive layer 4 can be lowered.

The thickness of the underlayer 3 is, for example, 5 nm or more, preferably 10 nm or more, more preferably 30 nm or more, and for example, 10,000 nm or less, preferably 5,000 nm or less.

The total light transmittance of the underlayer 3 is, for example, 70% or more, preferably 80% or more, more preferably 85% or more. The upper limit of the total light transmittance of the underlayer 3 is not limited, and is, for example, 100% or less. The total light transmittance of the underlayer 3 is determined based on JIS K 7375-2008.

The plane direction in the substrate 30 includes a direction of thermal shrinkage after heating the substrate 30. A heating temperature can be selected in accordance with heat resistance of the substrate 30. The plane direction in the substrate 30 includes a direction where a thermal shrinkage rate after heating the substrate 30 at 160° C. for 1 hour is, for example, 0.01% or more, preferably 0.05% or more, and for example, 1.0% or less, preferably 0.5% or less. When the thermal shrinkage rate of the substrate 30 is the above-described lower limit or more and the above-described upper limit or less, the first ridge 42 to be described later can be fabricated, while a crack of the transparent electrically conductive layer 4 is suppressed.

1.3 Transparent Electrically Conductive Layer 4

The transparent electrically conductive layer 4 is adjacent to one side in the thickness direction of the underlayer 3. Specifically, the transparent electrically conductive layer 4 is in contact with the one surface 31 in the thickness direction of the underlayer 3. The transparent electrically conductive layer 4 forms the one surface in the thickness direction of the laminate 1. The transparent electrically conductive layer 4 has a sheet shape extending in the plane direction. In the present embodiment, the transparent electrically conductive layer 4 is a single layer.

A one surface 41 in the thickness direction of the transparent electrically conductive layer 4 includes the first ridge 42 having a height of 3 nm or more. The transparent electrically conductive layer 4 includes the first ridge 42 having a height of preferably 4 nm or more, more preferably 5 nm or more, more preferably 7 nm or more, further more preferably 10 nm or more, particularly preferably 15 nm or more, and for example, 50 nm or less, preferably 30 nm or less, more preferably 20 nm or less. Since the transparent electrically conductive layer 4 includes the first ridge 42 having a height of the above-described lower limit or more and the above-described upper limit or less, it has excellent adhesion to another layer 5 to be described later. The number of the first ridge 42 is one or plural, and is preferably plural from the viewpoint of improving the adhesion.

In the present embodiment, from the description above, the number of the second ridge 32 (ref: FIG. 2) per unit length is 0. Therefore, the number of the first ridge 42 per unit length is greater than the number of the second ridge 32 (ref: FIG. 2) per unit length. When the number of the first ridge 42 per unit length is greater than the number of the second ridge 32 (ref: FIG. 2) per unit length, an adhesive force of the one surface 41 in the thickness direction of the transparent electrically conductive layer 4 is reliably improved, and the specific resistance of the transparent electrically conductive layer 4 can be reliably lowered.

Specifically, the number of the first ridge 42 per unit length is, for example, 1 piece/μm or more, preferably 2 pieces/μm or more, more preferably 3 pieces/μm or more, further more preferably 4 pieces/μm or more, particularly preferably 5 pieces/μm or more, most preferably 6 pieces/μm or more, and for example, 50 pieces/μm or less, preferably 30 pieces/μm or less, more preferably 20 pieces/μm or less.

The number of the first ridge 42 per unit length is counted by observing a cross section of the transparent electrically conductive layer 4 with TEM as described in Examples to be described later.

An average height of the first ridge 42 is 3 nm or more, preferably 4 nm or more, more preferably 5 nm or more, further more preferably 6 nm or more, particularly preferably 7 nm or more, and for example, 40 nm or less, preferably 20 nm or less, more preferably 15 nm or less, further more preferably 10 nm or less. The average height of the first ridge 42 is described in Examples to be described later. When the transparent electrically conductive layer 4 includes the first ridge 42 having the average height of the above-described lower limit or more and the above-described upper limit or less, it has the excellent adhesion to the other layer 5 to be described later.

In the present embodiment, the one surface 41 in the thickness direction of the transparent electrically conductive layer 4 further includes, for example, a flat portion 43. The flat portion 43 is disposed outside a ridge starting portion 431. The ridge starting portion 431 is a portion where the first ridge 42 starts ridging from the flat portion 43.

The height of the first ridge 42 is, in a cross-sectional view, a length from a one end portion 432 until a drooping point when the drooping point is obtained by drooping a line segment connecting the two ridge starting portions 431 along the thickness direction from the above-described one end portion 432 located at the most one side in the thickness direction. The height of the first ridge 42 is, for example, determined by observing the TEM image (cross-sectional observation).

Further, the transparent electrically conductive layer 4 is crystalline. Preferably, the transparent electrically conductive layer 4 does not include an amorphous region. Preferably, the transparent electrically conductive layer 4 consists of only the crystalline region.

Whether the transparent electrically conductive layer 4 is crystalline or amorphous is determined, for example, by the following test. The transparent electrically conductive layer 4 is immersed in an aqueous solution of hydrochloric acid of 5% by mass for 15 minutes, washed with water and dried, and resistance between two terminals between about 15 mm is measured on the one surface 41 of the transparent electrically conductive layer 4. When the resistance between the two terminals is 10 kΩ or less, the transparent electrically conductive layer 4 is crystalline, and when the above-described resistance between the two terminals is above 10 kΩ, the transparent electrically conductive layer 4 is amorphous.

The crystalline transparent electrically conductive layer 4 can sufficiently lower the specific resistance.

The transparent electrically conductive layer 4 includes a grain boundary 44. The grain boundary 44 includes a one end edge 441 leading to the one surface 41 in the thickness direction of the transparent electrically conductive layer 4.

The above-described grain boundaries 44 proceed to the other side in the thickness direction from each of the two one end edges 441, and they are connected in an intermediate portion in the thickness direction.

Further, the grain boundary 44 may further include an other end edge 442 which goes toward the other side in the thickness direction from the above-described one end edge 441 and leads to the other surface in the thickness direction of the transparent electrically conductive layer 4, that is, the one surface 31 in the thickness direction of the underlying layer 3.

Preferably, the grain boundary 44 does not include the other end edge 442, and the one grain boundary 44 includes the two one end edges 441. According to the configuration, the one surface 41 of the transparent electrically conductive layer 4 easily forms the first ridge 42.

Then, the above-described ridge starting portion 431 is located, for example, at the above-described one end edge 441 and/or is located near the above-described one end edge 441.

Specifically, each of the two ridge starting portions 431A in the first ridge 42A located in a left-side portion of FIG. 1 is located at the above-described one end edge 441. Although not shown, the one end edge 441 corresponding to the above-described first ridge 42A is, for example, an endless shape when viewed from the top, and there is the ridge starting portion 431A of the above-described first ridge 42A along the above-described one end edge 441 when viewed from the top.

Also, of the two ridge starting portions 431B in the first ridge 42B located in a right-side portion of FIG. 1, the ridge starting portion 431B at the left side is located near the one end edge 441 in the grain boundary 44 including the one end edge 441 and the other end edge 442. “Near” means that, for example, a distance between the two is within 15 nm, preferably within 10 nm. The remaining ridge starting portion 431B is located at the one end edge 441.

When the ridge starting portion 431 is located at and/or near the one end edge 441 of the grain boundary 44, the above-described first ridge 42 is reliably formed in a large number on the one surface 41 of the transparent electrically conductive layer 4. Therefore, the adhesion of the one surface 41 of the transparent electrically conductive layer 4 is excellent.

An example of the material for the transparent electrically conductive layer 4 includes metal oxide. The metal oxide includes at least one metal selected from the group consisting of In, Sn, Zn, Ga, Sb, Nb, Ti, Si, Zr, Mg, Al, Au, Ag, Cu, Pd, and W. Specifically, as the material for the transparent electrically conductive layer 4, preferably, indium-zinc composite oxide (IZO), indium-gallium-zinc composite oxide (IGZO), indium-gallium composite oxide (IGO), indium-tin composite oxide (ITO), and antimony-tin composite oxide (ATO) are used, preferably, indium-tin composite oxide (ITO) is used from the viewpoint of lowering the specific resistance.

The tin oxide content (SnO₂) in the indium tin composite oxide is, for example, 0.5% by mass or more, preferably 3% by mass or more, more preferably 6% by mass or more, and for example, below 50% by mass, preferably 25% by mass or less, more preferably 15% by mass or less.

The thickness of the transparent electrically conductive layer 4 is, for example, 15 nm or more, preferably 35 nm or more, more preferably 50 nm or more, further more preferably 75 nm or more, even more preferably 100 nm or more, particularly preferably 120 nm or more. When the thickness of the transparent electrically conductive layer 4 is the above-described lower limit or more, the grain boundary 44 does not include the other end edge 442, and the one grain boundary 44 can easily include the two one end edges 441. Therefore, the above-described first ridge 42 can be reliably provided in the transparent electrically conductive layer 4.

The thickness of the transparent electrically conductive layer 4 is the length in the thickness direction between the one surface 31 (flat surface) of the underlying layer 3 and the flat portion 43 in the one surface 41 in the thickness direction of the transparent electrically conductive layer 4.

The thickness of the transparent electrically conductive layer 4 is, for example, 500 nm or less, preferably 300 nm or less, more preferably 200 nm or less.

The thickness of the transparent electrically conductive layer 4 is measured by TEM observation (cross-sectional observation).

The total light transmittance of the transparent electrically conductive layer 4 is, for example, 60% or more, preferably 80% or more, more preferably 85% or more. The upper limit of the total light transmittance of the transparent electrically conductive layer 4 is not limited, and is, for example, 100% or less. The total light transmittance of the transparent electrically conductive layer 4 is determined based on MS K 7375-2008.

The specific resistance of the one surface 41 in the thickness direction of the transparent electrically conductive layer 4 is, for example, 3.0×10⁻⁴Ω·cm or less, preferably 2.5×10⁻⁴Ω·cm or less, more preferably 2.3×10⁻⁴Ω·cm or less, further more preferably 2.2×10⁻⁴Ω·cm or less, even more preferably 2.0×10⁻⁴Ω·cm or less, particularly preferably 1.9×10⁻⁴Ω·cm or less. The specific resistance of the one surface 41 in the thickness direction of the transparent electrically conductive layer 4 is, for example, 0.1∴10⁻⁴Ω·cm or more, preferably 0.5×10⁻⁴Ω·cm or more, more preferably 1.0×10⁻⁴Ω·cm or more, further more preferably 1.1×10⁻⁴Ω·cm or more. The specific resistance is measured by a four-terminal method.

Next, a method for producing the laminate 1 is described. In this method, each of the layers is disposed in a roll-to-roll method.

First, the long substrate layer 2 is prepared.

Next, a resin composition containing the above-described resin is coated onto the one surface 21 of the substrate layer 2. Thereafter, when the resin composition contains a curable resin, the curable resin is cured by heating or ultraviolet irradiation. Thus, the substrate 30 including the substrate layer 2 and the underlayer 3 in order toward one side in the thickness direction is prepared. In the present embodiment, since the resin composition does not contain the particles, while containing the resin, the above-described second ridge 32 (ref: FIG. 2) is not formed on the one surface 31 in the thickness direction of the underlayer 3.

A thermal shrinkage rate in a longitudinal direction (MD direction) of the substrate 30 when heated at, for example, 160° C. for 1 hour is not limited, and is, for example, 0.1% or more, preferably 0.2% or more, and for example, 2.0% or less, preferably 1.0% or less. The thermal shrinkage rate in a width direction (direction perpendicular to the longitudinal direction and the thickness direction) (TD direction) of the substrate 30 when heated at 160° C. for 1 hour is not limited, and is, for example, −0.2% or more, preferably 0.00% or more, more preferably 0.01% or more, further more preferably 0.05% or more, and for example, 1.0% or less, preferably 0.5% or less.

The thermal shrinkage rate of the substrate 30 is determined by the following formula.

Thermal shrinkage rate of the substrate 30 (%)=100×[length of the substrate 30 before heating−length of the substrate 30 after heating]/length of the substrate 30 before heating

Thereafter, the transparent electrically conductive layer 4 is formed on the one surface 31 in the thickness direction of the underlayer 3. A method for forming the transparent electrically conductive layer 4 includes, for example, a first step and a second step.

In the first step, an amorphous transparent electrically conductive layer 40 is formed on the one surface 31 in the thickness direction of the underlayer 3. The amorphous transparent electrically conductive layer 40 is formed on the one surface 31 in the thickness direction of the underlayer 3 by, for example, sputtering, preferably reactive sputtering.

In the sputtering, a sputtering device is used. The sputtering device includes a film forming roll. The film forming roll includes a cooling device. The cooling device is capable of cooling the film forming roll. The film forming roll is capable of cooling the underlayer 3 (the substrate 30 including the underlayer 3).

In the sputtering (preferably, reactive sputtering), the above-described metal oxide (sintered body thereof) is used as a target. A surface temperature of the film forming roll corresponds to a film forming temperature in the sputtering. The film forming temperature is, for example, 10.0° C. or less, preferably 0.0° C. or less, more preferably −2.5° C. or less, further more preferably −5.0° C. or less, further more preferably −7.0° C. or less, and for example, −50° C. or more, preferably −20° C. or more, further more preferably −10° C. or more.

When the surface temperature of the film forming roll is the above-described upper limit or less, the underlayer 3 (the substrate layer 3 including the underlayer 3) can be sufficiently cooled, so that the grain boundary 44 does not include the other end edge 442, and the one grain boundary 44 can easily obtain the transparent electrically conductive layer 4 including the two one end edges 441. Therefore, the first ridge 42 can be reliably formed on the one surface 41 of the transparent electrically conductive layer 4.

An example of the sputtering gas includes a rare gas. An example of the rare gas includes Ar. The sputtering gas may be mixed with a reactive gas. An example of the reactive gas includes oxygen. A ratio of an introduction amount of the reactive gas to the total introduction amount of the sputtering gas and the reactive gas is, for example, 0.1 flow rate % or more, preferably 0.5 flow rate % or more, more preferably 1.5 flow rate % or more, further more preferably 2.0 flow rate % or more, particularly preferably 2.5 flow rate % or more, and for example, 5 flow rate % or less, preferably 3 flow rate % or less.

The amorphous transparent electrically conductive layer 40 formed in the first step may not include the first ridge 42, or may already include the first ridge 42.

In the second step, the amorphous transparent electrically conductive layer 40 is crystallized, thereby forming a crystalline transparent electrically conductive layer 4. Specifically, in the second step, the amorphous transparent electrically conductive layer 40 is heated.

The heating temperature is, for example, 80° C. or more, preferably 110° C. or more, more preferably 130° C. or more, further more preferably 150° C. or more, and for example, 200° C. or less, preferably 180° C. or less, more preferably 175° C. or less, further more preferably 170° C. or less. The heating time is, for example, 1 minute or more, preferably 3 minutes or more, more preferably 5 minutes or more, and for example, 5 hours or less, preferably 3 hours or less, more preferably 2 hours or less. The heating is carried out, for example, under an atmospheric atmosphere.

Thus, the laminate 1 including the substrate layer 2, the underlayer 3, and the transparent electrically conductive layer 4 in order toward one side in the thickness direction is produced.

The thermal shrinkage rate in the longitudinal direction (MD direction) of the laminate 1 when heated at, for example, 160° C. for 1 hour is not limited, and is, for example, 0.1% or more, preferably 0.2% or more, and for example, 2.0% or less, preferably 1.0% or less. The thermal shrinkage rate in the width direction (direction perpendicular to the longitudinal direction and the thickness direction) (TD direction) of the laminate 1 when heated at 160° C. for 1 hour is not limited, and is, for example, −0.2% or more, preferably 0.00% or more, more preferably 0.01% or more, further more preferably 0.05% or more, and for example, 1.0% or less, preferably 0.5% or less.

When each of the thermal shrinkage rates of the laminate 1 in MD direction and TD direction is the above-described lower limit or more, the first ridge 42 can be reliably formed on the one surface 41 of the transparent electrically conductive layer 4.

The thermal shrinkage rate of the laminate 1 is determined by the following formula.

Thermal shrinkage rate of the laminate 1 (%)=100×[length of the laminate 1 before heating−length of the laminate 1 after heating]/length of the laminate 1 before heating

The total light transmittance of the laminate 1 is, for example, 60% or more, preferably 70% or more, more preferably 80% or more, further more preferably 85% or more. The upper limit of the total light transmittance of the laminate 1 is not limited, and is, for example, 100% or less. The total light transmittance of the substrate layer 2 is determined based on JIS K 7375-2008.

Thereafter, if necessary, the other layer 5 is disposed on the one surface in the thickness direction of the laminate 1, that is, on the one surface 41 in the thickness direction of the transparent electrically conductive layer 4. For example, a coating layer 51 is formed by coating. The other layer 51 includes, for example, a dimming functional coat layer and a metal paste layer. The other layer 5 is adjacent to the one surface 41 in the thickness direction of the transparent electrically conductive layer 4. Specifically, the other layer 5 is, for example, a dimming functional layer (voltage-driven dimming coating such as PDLC, PNLC, and SPD or current-driven dimming coating such as electrochromic (EC)) and a functional member such as metal paste containing silver, copper, and titanium.

### 2. Application of Laminate 1

The laminate 1 is, for example, used in an article. Specifically, the laminate 1 is an optical laminate, and examples of the above-described article include optical articles. Specifically, examples of the article include touch sensors, electromagnetic wave shields, dimming elements, photoelectric conversion elements, heat ray control members, light transmissive antenna members, light transmissive heater members, image display devices, and illumination.

### 3. Function and Effect of One Embodiment

In the laminate 1, the underlayer 3 does not include the second ridge 32 (ref: FIG. 2). Therefore, in the crystalline transparent electrically conductive layer 4, the orientation of the crystals can be aligned properly. Therefore, the specific resistance of the transparent electrically conductive layer 4 can be sufficiently lowered.

Further, the one surface 41 in the thickness direction of the transparent electrically conductive layer 4 includes the first ridge 42. Therefore, the transparent electrically conductive layer 4 has the excellent adhesion to the other layer 5 by an anchoring effect based on the first ridge 42.

### 4. Modified Examples

In each modified example below, the same reference numerals are provided for members and steps corresponding to each of those in the above-described one embodiment, and their detailed description is omitted. Further, each modified example can achieve the same function and effect as that of one embodiment unless otherwise specified. Furthermore, one embodiment and each modified example can be appropriately used in combination.

As shown in FIG. 2, in the laminate 1 of the modified example, the one surface 31 in the thickness direction of the underlayer 3 includes the second ridge 32 having a height of 3 nm or more. That is, in the laminate of the present invention, the one surface in the thickness direction of the underlayer may include the second ridge having a height of 3 nm or more, and the second ridge is not overlapped with the first ridge when projected in the thickness direction.

In the laminate 1 of the modified example, the above-described second ridge 32 is not overlapped with the first ridge 42 of the transparent electrically conductive layer 4 when projected in the thickness direction.

The number of the first ridge 42 per unit length is, for example, greater than the number of the second ridge 32 per unit length. When the number of the first ridge 42 per unit length is greater than the number of the second ridge 32 per unit length, the adhesive force of the one surface 41 in the thickness direction of the transparent electrically conductive layer 4 is reliably improved, and the specific resistance of the transparent electrically conductive layer 4 can be reliably lowered.

Specifically, the number of the second ridge 32 per unit length is, for example, 25 pieces/μm or less, preferably 20 pieces/μm or less, more preferably 10 pieces/μm or less, further more preferably 5 pieces/μm or less, and for example, 0 pieces/μm, further 1 piece/μm or more.

A ratio of the number of the second ridge 32 per unit length to the number of the first ridge 42 per unit length is, for example, 0.9 or less, preferably 0.5 or less, more preferably 0.3 or less, further more preferably 0.2 or less, particularly preferably 0.1 or less. The ratio of the number of the second ridge 32 per unit length to the number of the first ridge 42 per unit length is, for example, 0.0001 or more.

A value obtained by subtracting the number of the second ridge 32 per unit length from the number of the first ridge 42 per unit length is, for example, 1 piece/μm or more, preferably 2 pieces/μm or more, more preferably 5 pieces/μm or more, further more preferably 7 pieces/μm or more, particularly preferably 10 pieces/μm or more. The value obtained by subtracting the number of the second ridge 32 per unit length from the number of the first ridge 42 per unit length is, for example, 30 pieces/μm or less.

The method for providing the above-described second ridge 32 in the underlayer 3 is not particularly limited.

For example, as shown in FIG. 7, when the second ridge 32 is overlapped with the first ridge 42 of the transparent electrically conductive layer 4 when projected in the thickness direction, the orientation of the crystals is hardly aligned in the transparent electrically conductive layer 4 in the crystallization of the first ridge 42, that is, the growth of the crystals is inhibited, and thus, the specific resistance of the transparent electrically conductive layer 4 is increased.

However, in the laminate 1 of the modified example, as shown in FIG. 2, since the second ridge 32 is not overlapped with the first ridge 42 of the transparent electrically conductive layer 4 when projected in the thickness direction, the above-described problem does not occur, and the specific resistance of the transparent electrically conductive layer 4 can be lowered.

Of one embodiment and the modified examples, preferably one embodiment is used. In one embodiment, as shown in FIG. 1, since the one surface 31 of the underlayer 3 does not include the second ridge 32, the above-described orientation of the crystals in the transparent electrically conductive layer 4 can be further aligned. Therefore, the specific resistance of the transparent electrically conductive layer 4 can be sufficiently lowered.

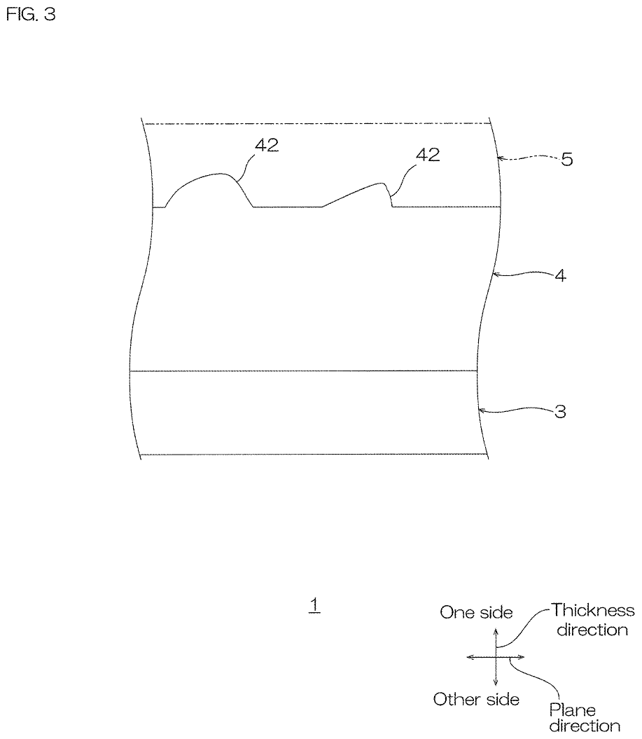

As shown in FIG. 3, the laminate 1 does not include the substrate layer 2, and includes the underlayer 3 and the transparent electrically conductive layer 4.

### EXAMPLES

Next, the present invention is further more specifically described based on Examples and Comparative Examples. The present invention is however not limited by Examples and Comparative Examples. The specific numerical values in mixing ratio (content ratio), property value, and parameter used in the following description can be replaced with upper limit values (numerical values defined as “or less” or “below”) or lower limit values (numerical values defined as “or more” or “above”) of corresponding numerical values in mixing ratio (content ratio), property value, and parameter described in the above-described “DESCRIPTION OF EMBODIMENTS”.

### Example 1

A coating film was formed by coating an ultraviolet curable resin onto the one surface 21 in the thickness direction of the substrate layer 2 made of a long PET film (thickness of 50 μm, manufactured by Toray Industries, Inc.). An ultraviolet curable resin composition contained an acrylic resin. Next, the coating film was cured by ultraviolet irradiation, thereby forming the underlayer 3. The thickness of the underlayer 3 was 2 μm. Thus, the substrate 30 including the substrate layer 2 and the underlayer 3 in order in the thickness direction was fabricated.

Next, the amorphous transparent electrically conductive layer 40 was formed on the one surface 31 in the thickness direction of the underlayer 3 by a reactive sputtering method (first step). In the reactive sputtering method, a DC magnetron sputtering device was used.

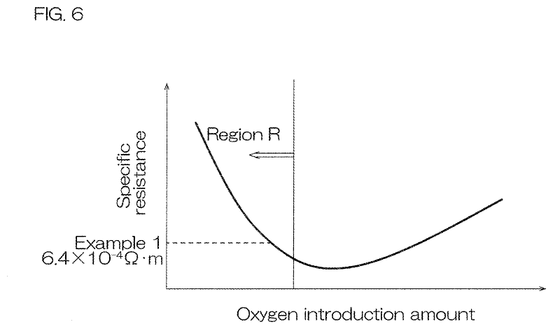

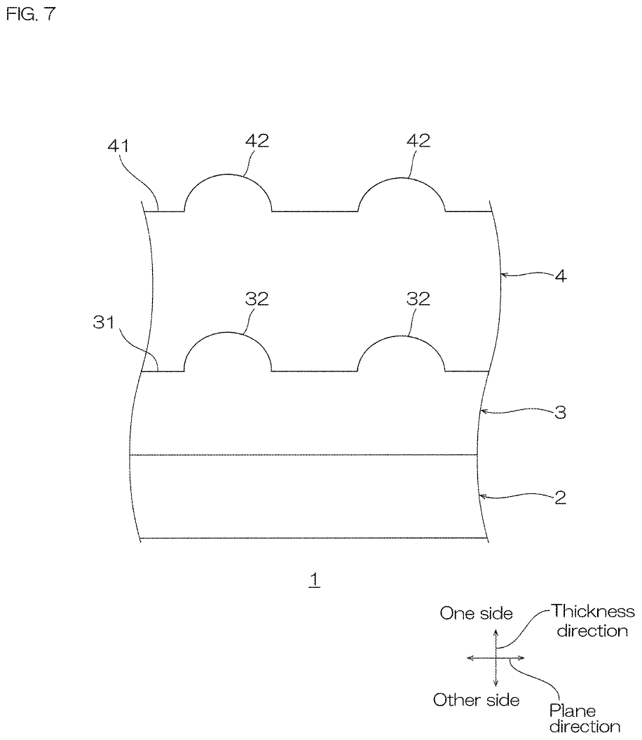

The conditions of the sputtering in Examples are as follows. As a target, a sintered body of indium oxide and tin oxide was used. The tin oxide concentration in the sintered body was 10% by mass. A DC power supply was used to apply a voltage to the target. The horizontal magnetic field strength on the target was set at 90 mT. The film forming temperature was set at −8° C. In the present application, the film forming temperature is the surface temperature of the film forming roll and is the same as the temperature of the substrate 30. Further, a film forming chamber was evacuated until the ultimate vacuum of the film forming chamber in the DC magnetron sputtering device reached 0.6×10⁻⁴ Pa, and thereafter, Ar as a sputtering gas and oxygen as a reactive gas were introduced into the film forming chamber, and the air pressure in the film forming chamber was set at 0.4 Pa. The ratio of the oxygen introduction amount to the total introduction amount of Ar and oxygen introduced into the film forming chamber was about 2.6 flow rate %. The oxygen introduction amount was, as shown in FIG. 6, adjusted so that it was within a region R of a specific resistance-oxygen introduction amount curve, and the specific resistance of the amorphous transparent electrically conductive layer 40 was 6.4×10⁻⁴Ω·cm. The specific resistance-oxygen introduction amount curve shown in FIG. 6 was fabricated by examining in advance oxygen introduction amount dependence of the specific resistance of the amorphous transparent electrically conductive layer 40 when the amorphous transparent electrically conductive layer 40 was formed by a reactive sputtering method under the same conditions as the above-described conditions other than the oxygen introduction amount.

Next, the amorphous transparent electrically conductive layer 40 was crystallized by heating in a hot air oven (second step). The heating temperature was set at 160° C., and the heating time was set at 1 hour. The thickness of the crystalline transparent electrically conductive layer 4 was 145 nm. The thickness of the transparent electrically conductive layer 4 is described later.

Thus, the laminate 1 including the substrate layer 2, the underlayer 3, and the crystalline transparent electrically conductive layer 4 in order on the one surface in the thickness direction was produced (ref: FIG. 1).

### Example 2

The laminate 1 was produced in the same manner as in Example 1. However, the ratio of the oxygen introduction amount to the total introduction amount of Ar and oxygen introduced into the film forming chamber was changed to about 1.3 flow rate %, and the thickness of the transparent electrically conductive layer 4 was changed to 56 nm.

### Comparative Example 1

The laminate 1 was produced in the same manner as in Example 1. However, the film forming temperature was changed to 80° C., the ratio of the oxygen introduction amount to the total introduction amount of Ar and oxygen introduced into the film forming chamber was changed to about 1.6 flow rate %, and the thickness of the transparent electrically conductive layer 4 was changed to 32 nm.

### Comparative Example 2

The laminate 1 was produced in the same manner as in Comparative Example 1. However, an ultraviolet curable resin composition including an acrylic resin and silica particles having a particle size of 20 nm was used (ref: FIG. 7).

<Evaluation>

As for each of the transparent electrically conductive layers 4 of Examples and Comparative Examples, the following items were evaluated. The results are shown in Table 1.

[Thickness of Transparent Electrically Conductive Layer 4]

The thickness of the transparent electrically conductive layer 4 of each of the laminates 1 in Examples and Comparative Examples was measured by FE-TEM observation. Specifically, first, a sample for cross-sectional observation of each of the transparent electrically conductive layers 4 in Example 1, Example 2, Comparative Example 1, and Comparative Example 2 was fabricated by an FIB micro sampling method. In the FIB micro sampling method, an FIB device (trade name “FB2200”, manufactured by Hitachi, Ltd.) was used, and an acceleration voltage was set at 10 kV. Next, the thickness of the transparent electrically conductive layer 4 in the sample for cross-sectional observation was measured by FE-TEM observation. In the FE-TEM observation, an FE-TEM device (trade name “JEM-2800”, manufactured by JEOL, Ltd.) was used, and the acceleration voltage was set at 200 kV.

[Cross-Sectional Observation of First Ridge 42 and Second Ridge 32, and Counting of Number of First Ridge 42]

After each of the transparent electrically conductive laminates of Examples and Comparative Examples was cross-sectionally adjusted by the FIB micro sampling method, the cross-section of each of the underlayer 3 and the transparent electrically conductive layer 4 was subjected to FE-TEM observation to confirm a presence of each of the first ridge 42 and the second ridge 32. In addition, the number of the first ridges 42 existing in a length of 1 μm on the one surface 41 in the thickness direction of the transparent electrically conductive layer 4 was counted. The observation magnification was set so that the presence or absence and the height of the first ridge 42 and the second ridge 32 could be observed.

The device and the measurement conditions are as follows.

FIB device: FB2200 manufactured by Hitachi, Ltd., acceleration voltage: 10 kV

FE-TEM device: JEM-2800 manufactured by JEOL, Ltd., acceleration voltage: 200 kV

As a result, in each of Example 1 and Example 2, the first ridge 42 was observed, but the second ridge 32 was not observed.

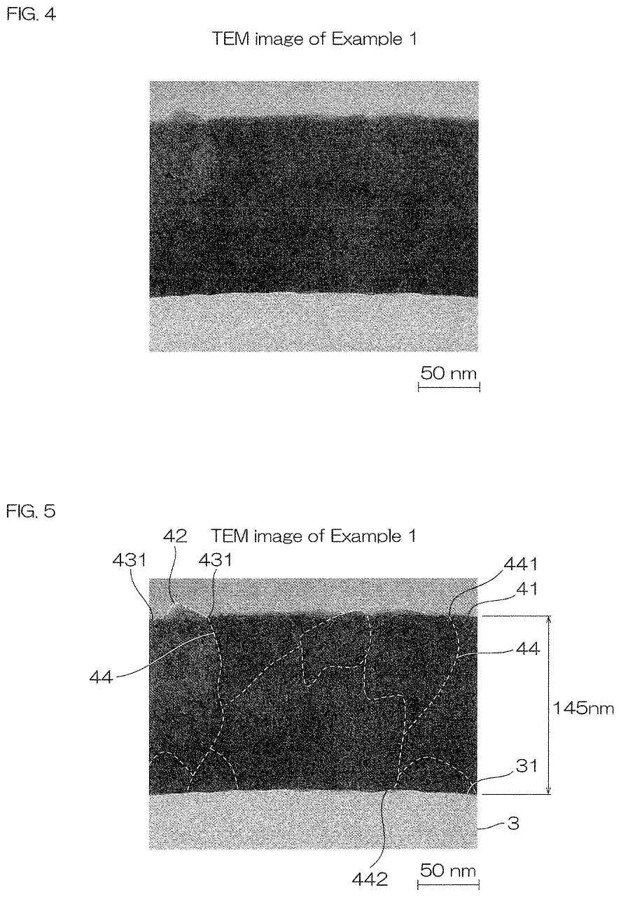

Of the first ridge 42 in Example 1, the height of the highest ridge was 15 nm. The average height of the first ridge 42, which was obtained by selecting the 10 optional first ridges 42 in Example 1, was 7 nm. In other words, the average height of the first ridge 42 was determined as an average height of the 10 optional first ridges 42. Further, FIG. 5 shows a diagram drawing the grain boundary 44 by a broken line in FIG. 4.

Of the first ridge 42 in Example 2, the height of the highest ridge was 14 nm. The average height of the first ridge 42, which was obtained by selecting the 10 optional first ridges 42 in Example 2, was 5 nm.

In Comparative Example 1, neither the first ridge 42 nor the second ridge 32 was observed.

In Comparative Example 2, both the first ridge 42 and the second ridge 32 were observed (ref: FIG. 7). Each of the heights of the first ridge 42 and the second ridge 32 in Comparative Example 2 was 11 nm.

In addition, the number of the first ridge 42 per unit length of each of the first ridges 42 of Example 1, Example 2, and Comparative Example 1 was counted. As a result, in Example 1, it was 7 pieces/μm. In Example 2, it was 2 pieces/μm. In Comparative Example 2, it was 5 pieces/μm.

[Resistance Properties of Transparent Electrically Conductive Laminate]

The specific resistance of the one surface 41 in the thickness direction of each of the transparent electrically conductive layers 4 of Examples and Comparative Examples was measured by the four-terminal method in conformity with JIS K7194 (1994), and thereafter, a specific resistance value was determined by multiplying the measured value by each of the thicknesses of Examples.

[Thermal Shrinkage Rate of Substrate 30 and Laminate 1]The thermal shrinkage rate of the substrate 30 of Example 1 after being heated at 160° C. for 1 hour was measured. As a result, the thermal shrinkage rate in MD direction of the substrate 30 was 0.5%, which was 0.1% in TD direction of the laminate 1.

The thermal shrinkage rate of the laminate 1 of Example 1 after being heated at 160° C. for 1 hour was measured. As a result, the thermal shrinkage rate in MD direction of the laminate 1 was 0.3%, which was 0.1% in TD direction of the laminate 1.

[Table 1]

TABLE 1

| | | Thickness of | First Ridge | | | | | Specific |
|---|---|---|---|---|---|---|---|---|
| | | Transparent | (Transparent Electrically | | | | | Resistance |
| | | Electrically | Conductive Layer) | | | Second Ridge | | of Transparent |
| Ex.• | Film Forming | Conductive | | Highest | Average | (Underlayer) | | Electrically |
| Comparative | Temperature | Layer | Presence or | Height | Height | Presence or | Height | Conductive Layer |
| Ex. | (° C.) | (nm) | Absence | (nm) | (nm) | Absence | (nm) | ×10⁻⁴ Ω · cm |
| Ex. 1 | −8 | 145 | Presence | 15 | 7 | Absence | — | 1.9 |
| Ex. 2 | −8 | 56 | Presence | 14 | 5 | Absence | — | 1.8 |
| Comparative | 80 | 32 | Absence | — | — | Absence | — | 1.9 |
| Ex. 1 | | | | | | | | |
| Comparative | 80 | 32 | Presence | 11 | — | Presence | 11 | 2.6 |
| Ex. 2 | | | | | | | | |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The laminate of the present invention is used for optical articles.

### Description of Reference Numerals

1 Laminate
3 Underlayer
31 One surface in thickness direction of underlayer
32 Second ridge
4 Transparent electrically conductive layer
41 One surface in thickness direction of transparent electrically conductive layer
42 First ridge
431 Ridge starting portion
44 Grain boundary
441 One end edge

1. A laminate comprising:
an underlayer and a crystalline transparent electrically conductive layer adjacent to a one surface in a thickness direction of the underlayer, wherein
the underlayer includes a resin,
a one surface in the thickness direction of the transparent electrically conductive layer includes a first ridge having a height of 3 nm or more,
the one surface of the underlayer may include a second ridge having a height of 3 nm or more, and
the second ridge is not overlapped with the first ridge when projected in the thickness direction.

2. The laminate according to claim 1, wherein
the number of the first ridge per unit length is greater than the number of the second ridge per unit length.

3. The laminate according to claim 1, wherein
the underlayer does not include the second ridge.

4. The laminate according to claim 1, wherein
the transparent electrically conductive layer includes a grain boundary having an end edge leading to the one surface of the transparent electrically conductive layer, and
a ridge starting portion at which the first ridge starts ridging is located at or near the end edge.

5. The laminate according to claim 3, wherein
the transparent electrically conductive layer includes a grain boundary having an end edge leading to the one surface of the transparent electrically conductive layer, and
a ridge starting portion at which the first ridge starts ridging is located at or near the end edge.
